(19) United States
(12) Patent Application Publication
(10) Pub. No.: US 2014/0027914 A1
(43) Pub. Date: Jan. 30, 2014

(54) PROTECTION OF UNDER-LAYER CONDUCTIVE PATHWAY

(71) Applicants: Hideyuki Tomizawa, Rensselaer, NY (US); Masao Ishikawa, Malta, NY (US); Hideshi Miyajima, Clifton Park, NY (US)

(72) Inventors: Hideyuki Tomizawa, Rensselaer, NY (US); Masao Ishikawa, Malta, NY (US); Hideshi Miyajima, Clifton Park, NY (US)

(73) Assignee: TOSHIBA AMERICA ELECTRONIC COMPONENTS, INC., Irvine, CA (US)

(21) Appl. No.: 13/556,338

(22) Filed: Jul. 24, 2012

(51) Int. Cl. H01L 23/538; H01L 21/768

(52) U.S. Cl. 257/762; 438/637; 257/E23.174; 257/E21.577

(57) ABSTRACT

Systems and methods are presented for preventing removal of material comprising a metal gate during removal of a mask layer in a semiconductor structure. Upon exposure of the metal line during formation of a via opening the exposed portion of the metal line undergoes chemical modification to form a passivation layer. The passivation layer is subsequently covered by an etch selectivity layer, wherein the etch selectivity layer prevents removal of at least one of a portion of the metal line or the passivation layer during removal of a hard mask layer comprising the semiconductor structure. In an alternate approach, the metal line is formed with a capping layer which, following exposure by a via opening formed in the semiconductor structure, is chemically modified to form a layer having etch selectivity to acts as a protective layer during removal of a hard mask layer comprising the semiconductor layer.

### FIELD

Embodiments described herein relate generally to methods and systems for protection of conductive pathways in semiconductor devices.

### BACKGROUND

Silicon large-scale integrated circuits, among other device technologies, are applied ubiquitously throughout modern society to accommodate the needs for digital information and digital control. An integrated circuit may comprise a plurality of semiconductor devices, such as transistors or the like, which can be produced according to a variety of techniques. To facilitate increased integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc., of resultant integrated circuits. However, as semiconductor devices and device features have become smaller, conventional fabrication techniques have become limited in their ability to produce finely defined features.

Conventionally, front-end-of-line (FEOL) fabrication processing of an integrated circuit relates to patterning of devices (e.g., transistors, capacitors, resistors, etc.) in the semiconductor. Formation of interconnects to facilitate connection of the various devices conventionally occurs during back-end-of-line (BEOL) fabrication. By way of example, interconnects are formed during BEOL fabrication of an integrated circuit structure to facilitate connection between conductive patterns comprising conductive lines separated by interwiring spacings, and a plurality of interconnect lines, such as bus lines, bit lines, word lines and logic interconnect lines comprising an integrated circuit structure. A particular aspect in interconnect formation is a via, where a via can be formed in an insulator, dielectric, or similar structure, and facilitates connection between the various conductive elements comprising the integrated circuit structure. However, owing to the number of operations required to form the via, and associated structures, processing conflicts can occur whereby an operation required to create/modify one structure can have a deleterious effect on a nearby structure.

FIG. 13 illustrates a conventional approach for construction and interconnection of a via and a conductive pathway such as a metal line. A semiconductor stack is depicted, where a via is to be formed connecting opening 395 with metal line 320. The semiconductor stack comprises a substrate layer 310 which has been patterned to facilitate therein formation of a metal line 320 and barrier layer 325, with barrier layer 325 preventing diffusion of atoms comprising the metal line 320 into the substrate layer 310. A diffusion barrier layer 330 is formed thereover, with the stack being constructed to further comprise a dielectric layer 340, a tetraethyl orthosilicate (TEOS) layer 350, a hard mask layer 360 (which has been patterned with an opening as depicted), an organic planarization layer (OPL) 370 formed thereon, an Anti-Reflection coating (ARC) layer 380 (e.g., SiARC), and a resist layer 390, which has undergone patterning to form opening 395, e.g., as part of a via lithography operation.

As illustrated in FIG. 14, a partial via etch operation has been performed such that resist layer 390, ARC layer 380, and OPL 370 have been removed and opening 395 further extended into delectric layer 340. In an aspect, the patterning of the hard mask layer 360 can constrain formation of the larger opening 397.

As illustrated in FIG. 15, a trench etch operation has been performed whereby the opening 395 has extended into the diffusion barrier layer 330. However, the trench etch operation can result in unwanted removal of material from the diffusion barrier layer.

As illustrated in FIG. 16, the hard mask layer 360 is to be removed, with a typical removal operation comprising a wet etching process.

However, the trench etch operation (FIG. 15) can be challenging owing to the lack of control regarding the amount of diffusion barrier layer 330 which is removed during the respective operations. A situation can occur where metal line 320 is exposed too early, for example, too much barrier diffusion layer 330 is removed during the trench etch operation (FIG. 15) and further removed during the hard mask layer 360 removal operation illustrated in FIG. 16. As illustrated in FIG. 17, owing to a wet etching operation being anisotropic in nature, upper surface 399 of metal line 320 becomes exposed, whereby Cu forming metal line 320 may be removed in a vertical direction V, and Cu may be further removed in the lateral direction L resulting in formation of an undercut beneath diffusion barrier layer 330.

As illustrated in FIG. 18, the TEOS layer 350 undergoes a faceting operation to facilitate widening of the openings 395 and 397 to enable improved formation of the connector in the openings 395 and 397. During the TEOS faceting operation further removal of the exposed Cu of metal line 320 may occur thereby exacerbating further the degree of undercutting beneath diffusion barrier layer 330. With the combination of etching operations for the hard mask layer 360 removal, lack of control of diffusion barrier layer 330 removal, and the TEOS faceting, undesired removal of material from the metal line 320 occurs at the exposed surface 399 of the metal line 320. The volume of material removed from metal line 320 can be of such a degree to negatively impact operation of the semiconductor device owing to, for example, increased resistance (e.g., as a result of thinning metal line 320) at the metal line at the bottom of opening 395.

Further, owing to the undercut(s) formed during hard mask layer 360 removal and/or during TEOS faceting, during subsequent formation of a connector (e.g., during metallization of opening 395) it may not be possible to fill the undercut regions and thus connectors are formed with voids occurring at the undercut, which can lead to impaired operation of the connector compared to that anticipated.

Hence, while technologies facilitate further miniaturization of semiconductor related devices and components, issues regarding construction of the vias and interconnects are still to be addressed.

### SUMMARY

A simplified summary is provided herein to help enable a basic or general understanding of various aspects of exemplary, non-limiting embodiments that follow in the more detailed description and the accompanying drawings. This summary is not intended, however, as an extensive or exhaustive overview. Instead, the sole purpose of this summary is to present some concepts related to some exemplary non-limiting embodiments in a simplified form as a prelude to the more detailed description of the various embodiments that follow.

The subject innovation presents various techniques related to preventing unwanted removal of a metal line during via formation in a semiconductor device, wherein the via can be subsequently filled with conductive material to facilitate formation of an interconnect connecting with the metal line.

In an exemplary, non-limiting embodiment, the metal line can be protected as part of the formation of the via opening. As a semiconductor stack is constructed, a metal line can be incorporated therein to subsequently comprise an electrical circuit. A via can be formed into the semiconductor stack to expose a surface of the metal line. A silicidation operation can be performed during which material at the surface of the metal line is exposed to an atmosphere comprising silicon, for example, the surface of metal line is exposed to a soaking atmosphere comprising SiH₄. The silicon-rich atmosphere results in the formation of a silicide layer resulting from diffusion of Si into the body of the metal line. In an exemplary, non-limiting embodiment, the metal line can comprise of Cu, with the silicide layer comprising copper silicide, where the silicide layer can act as a passivation layer. An oxide layer (e.g., SiO₂) is formed on top of the silicide layer. During subsequent removal of a hard mask layer, the oxide layer acts as an etch stop layer owing to the etch selectivity of the oxide layer relative to the etchant utilized to remove the hard mask layer. During a TEOS faceting operation the oxide layer can be removed, exposing the silicide layer. The via can be subsequently filled with conductive material to facilitate formation of an interconnect connecting with the silicide layer of the metal line.

In another exemplary, non-limiting embodiment, after the metal line has been formed in a substrate, the metal line can have a capping layer formed thereon. The semiconductor stack is further constructed, followed by a via being formed in the semiconductor stack resulting in the capping layer being exposed. The capping layer can be subsequently converted to an oxide layer to facilitate protection of the metal line during further processing of the semiconductor stack, for example, during removal of a hard mask layer. In an exemplary, non-limiting embodiment, the metal line comprises Cu, and the capping layer comprises Mn. During the oxidation conversion, the capping layer (comprising Mn) is converted to an oxide layer (comprising manganese oxide). During subsequent processing, faceting of a TEOS layer, for example, the oxide layer can be removed and the via opening can be subsequently filled with conductive material to facilitate formation of an interconnect connecting to the metal line.

### BRIEF DESCRIPTION OF THE DRAWINGS

FIG. 1 is a block diagram illustrating a non-limiting, exemplary embodiment of a structure comprising a metal line.

FIG. 2 is a block diagram illustrating a non-limiting, exemplary embodiment of a structure comprising a metal line during via formation.

FIG. 3 is a block diagram illustrating a non-limiting, exemplary embodiment of a structure comprising a metal line undergoing protective layering.

FIG. 4 is a block diagram illustrating a non-limiting, exemplary embodiment of a layer being removed from a structure comprising a metal line.

FIG. 5 is a block diagram illustrating a non-limiting, exemplary embodiment of a structure comprising a metal line undergoing layer faceting and removal of a protective layer.

FIG. 6 illustrates a flow for protecting a metal line during formation of a via in accordance with one or more embodiments of the subject innovation.

FIG. 7 is a block diagram illustrating a non-limiting, exemplary embodiment of a structure comprising a metal line.

FIG. 8 is a block diagram illustrating a non-limiting, exemplary embodiment of a structure comprising a metal line during via formation.

FIG. 9 is a block diagram illustrating a non-limiting, exemplary embodiment of a structure comprising a metal line undergoing protective layering.

FIG. 10 is a block diagram illustrating a non-limiting, exemplary embodiment of a layer being removed from a structure comprising a metal line.

FIG. 11 is a block diagram illustrating a non-limiting, exemplary embodiment of a structure comprising a metal line undergoing layer faceting and removal of a protective layer.

FIG. 12 illustrates a flow for protecting a metal line during formation of a via in accordance with one or more embodiments of the subject innovation.

FIG. 13 illustrates a structure comprising a metal line.

FIG. 14 illustrates a structure comprising a metal line during via formation.

FIG. 15 illustrates a structure comprising a metal line during via formation.

FIG. 16 illustrates a layer being removed from a structure comprising a metal line structure.

FIG. 17 illustrates material being removed from a metal line structure.

FIG. 18 illustrates material being removed from a metal line structure.

### DETAILED DESCRIPTION

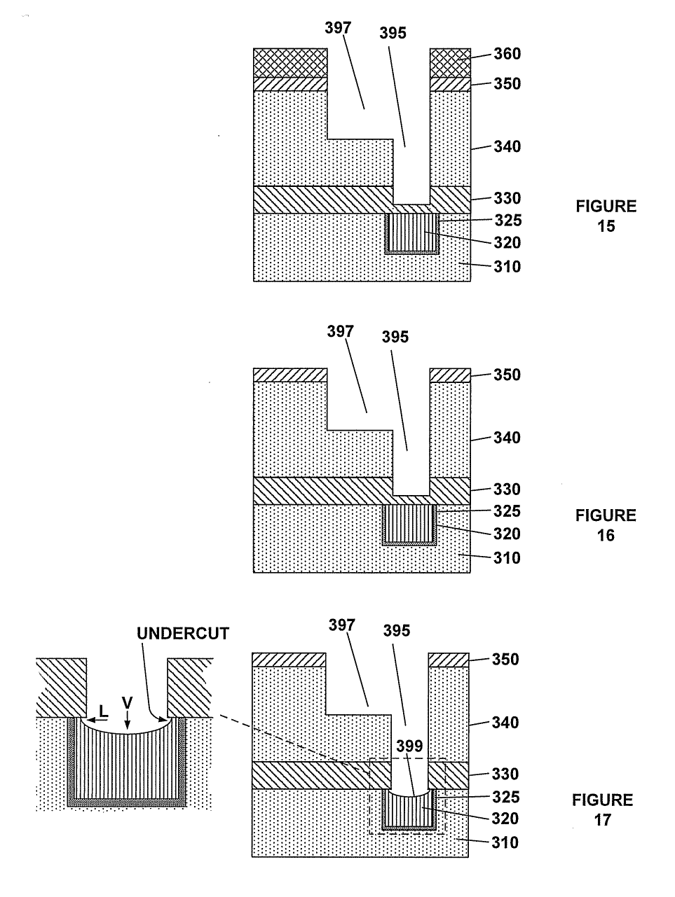

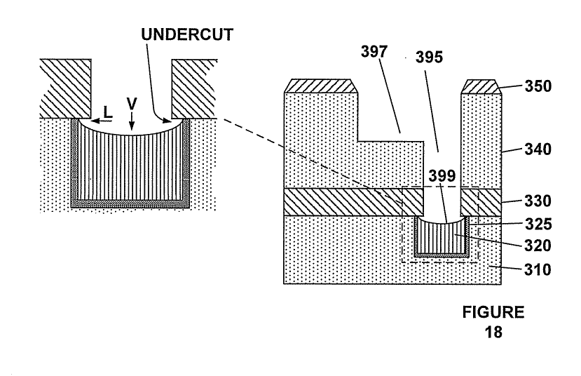

The subject innovation presents various techniques relating to preventing unwanted removal of a conductive pathway, such as a metal line, during via formation in a semiconductor device. As described in the background, given the number of operations required to form the via, and any associated structures, processing conflicts can occur whereby an operation required to be conducted in the modification of one structure can have a deleterious effect on a nearby structure. As depicted in FIG. 17, owing to the inability to accurately control the volume of diffusion barrier layer 330 removed during respective operations (e.g., trench etch operation (FIG. 15) and the TEOS/diffusion barrier modification operations (FIG. 17)) an undesired removal of material from the surface 399 of the metal line 320 occurs.

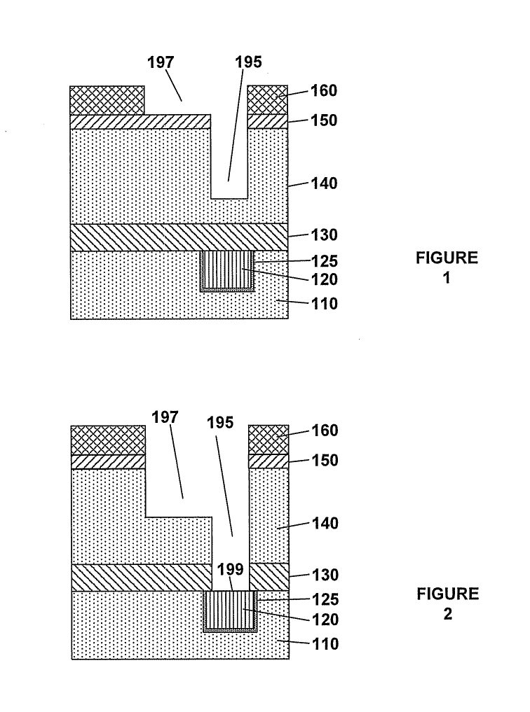

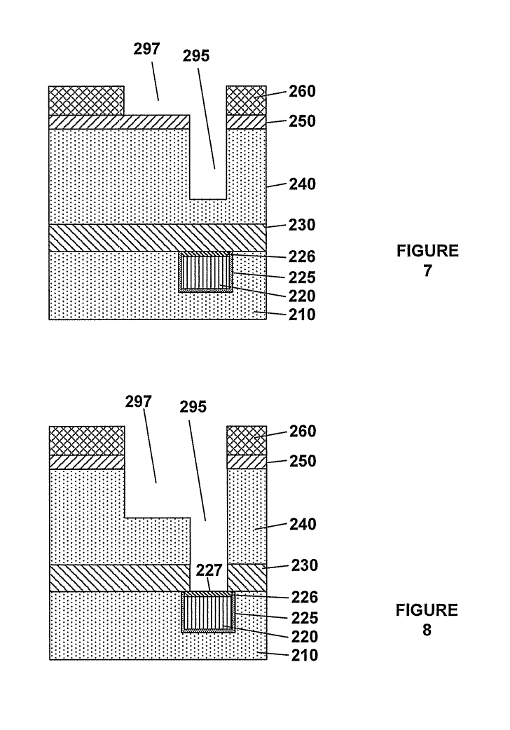

Presented herein are embodiments whereby a surface region of a metal line is protected and thus removal of material from the metal line is prevented during formation of a via to connect with the metal line. In an exemplary, non-limiting embodiment, the metal line can be protected as part of the formation of the via opening (FIGS. 1-6), while in an alternate exemplary, non-limiting embodiment, the metal line can have a protective layer formed thereon prior to subsequent formation of a semiconductor stack (FIGS. 7-11).

### Process for Metal Line Protection During via Formation

FIGS. 1-5 illustrate a series of exemplary, non-limiting embodiments to facilitate formation of a protective layer on a metal line during formation of a via, where the via can be subsequently filled with conductive material to form an interconnect to facilitate electrical coupling with the metal line.

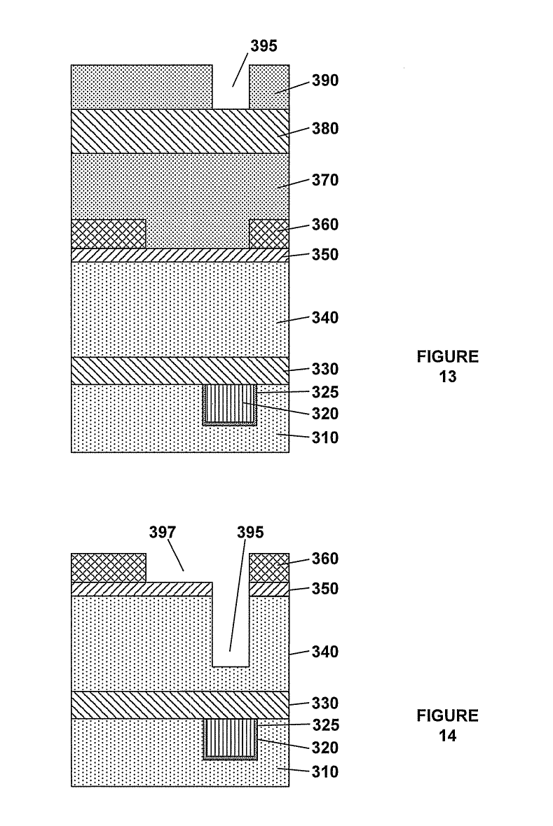

FIG. 1 illustrates an intermediate structure for the formation of a via (and a subsequently formed interconnect) to connect with a metal line. It is to be appreciated that the various layers comprising the exemplary semiconductor stack depicted in FIGS. 1-5 (and similarly in FIGS. 7-11) are presented to facilitate understanding of the various concepts presented herein, while the various concepts presented herein can be applied to any suitable semiconductor stack structure. For example, the semiconductor stack illustrated in FIGS. 1-5 (and similarly in FIGS. 7-11) can be an intermediate stage in process operations such that the semiconductor stack is an intermediate stage in a via formation process having an initial structure similar to that illustrated in FIG. 13. The semiconductor stack comprises a substrate layer 110 which has been patterned to facilitate formation of a metal line 120 (and barrier layer 125) therein. A diffusion barrier layer 130 is formed thereover, with the semiconductor stack being further constructed to comprise a dielectric layer 140, a TEOS layer 150, and a hard mask layer 160 (which has been patterned with an opening as depicted), with openings 195 and 197 partially extending into the semiconductor stack. In comparison with the initial structure presented in FIG. 13, the organic planarization layer (OPL) 370, the Anti-Reflection coating (ARC) layer 380, and resist layer 390, have been removed. Effectively, the structure illustrated in FIG. 1 can be considered comparable to that illustrated in FIG. 14, whereby a partial via etch operation has been performed.

Metal line 120 can be comprised of any suitable conductive material such as aluminum, copper, alloy, etc. In the various embodiments presented herein, metal line 120 is referenced as being comprised of Cu, however, it is to be appreciated that the various embodiments can be applied equally to a protective layer being formed on a metal line comprising any suitably conductive material.

As depicted in FIG. 2, a trench etch operation has been performed such that openings 195 and 197 further extend into the semiconductor stack, with further material being removed from TEOS layer 150 and dielectric layer 140, along with material from diffusion barrier layer 130. As shown, in an aspect, the width of combined openings 195 and 197 can be limited by the width of the opening previously formed in the hard mask layer 160.

In comparison with the conventional process depicted in FIGS. 13-17, during the trench etch operation, the depth of opening 195 is allowed to extend such that the upper surface 199 of metal line 120 is exposed.

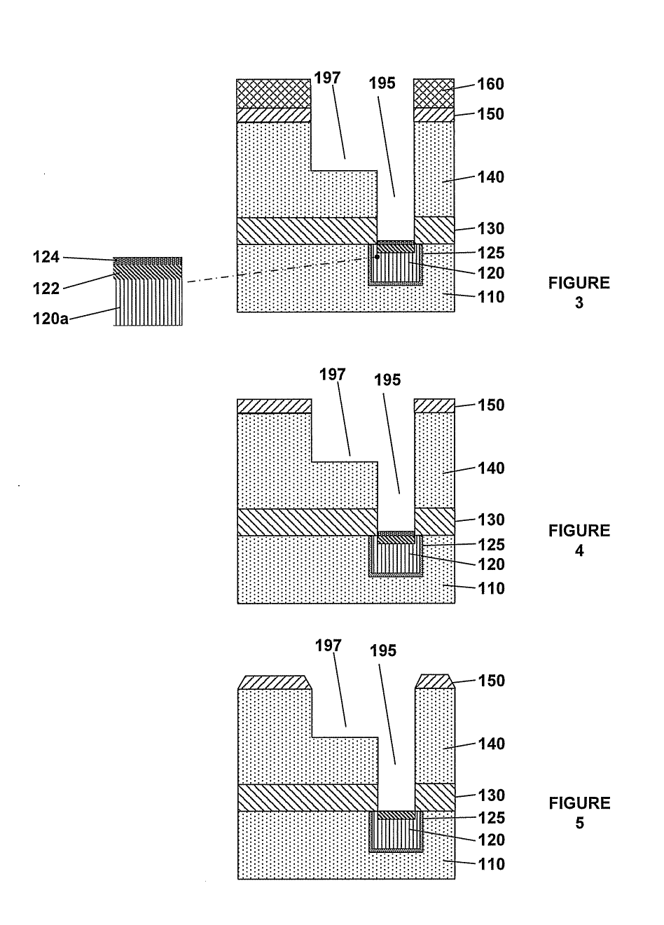

FIG. 3 illustrates silicidation and oxidation operations being performed. In an exemplary, non-limiting embodiment, any suitable silicidation operation can be performed, for example a thermal process during which material at the surface 199 of metal line 120 is exposed to an atmosphere comprising silicon. For example, an annealing process can be conducted whereby surface 199 is exposed to a soaking atmosphere comprising SiH₄. The silicon-rich atmosphere results in the formation of a silicide layer 122 (e.g., comprising copper silicide) at surface 199 located at the bottom of via opening 195. Further, the silicidation process can be followed by an oxidation process, whereby an oxide layer 124 (e.g., comprising SiO₂) forms on top of the silicide layer 122. A portion 120a of the metal line 120 is shown with the silicide layer 122 depicted with the oxide layer 124 formed above. Modes of formation of the respective layers can be diffusion of the Si into the body of metal line 120, thereby forming a region of copper silicide comprising silicide layer 122 in the metal line 120, while the oxide layer 124, e.g., comprising SiO₂, is deposited onto silicide layer 122.

In an exemplary, non-limiting embodiment, silicide layer 122 can act to isolate the Cu of the metal line from the subsequent oxide formation process. For example, Cu reacts with oxygen to form copper oxide (e.g., CuO, etc.), in effect the copper oxide can be considered a corrosion product and is unwanted. The formation of copper oxide will result in the depletion of Cu in the metal line, thereby reducing the final volume of metal line 120. Hence, upon subsequent removal of the copper oxide, less Cu comprises metal line 120, and a situation may result where the final volume of Cu in the metal line 120 is equivalent to the volume of Cu in metal line 320 (see FIG. 17). However, by forming the silicide layer 122, in an exemplary, non-limiting embodiment, it is possible that no free metal (e.g., Cu) remains at the surface of the metal line 120 and hence when the oxidizing atmosphere is subsequently utilized, formation of copper oxide is precluded and thus only SiO₂ is formed. The silicide layer 122 can be considered to be an intermetallic layer acting as a passivation layer preventing the formation of copper oxide. Further, while the metal line 120 has a high conductivity, the conductivity of the silicide layer 122 is still of sufficient magnitude to facilitate electrical flow between the via subsequently formed in final openings 195 and 197 and the underlying metal line 120.

FIG. 4 depicts hard mask layer 160 being removed. Any suitable technique can be utilized to remove the hard mask, for example a wet etch. During removal of the hard mask layer 160, oxide layer 124 has high selectivity to wet etch chemistry and thus acts to isolate metal line 120 and silicide layer 122 from the wet etch, thereby preventing unwanted removal of material from the metal line 120 and/or silicide layer 122 during removal of the hard mask layer 160.

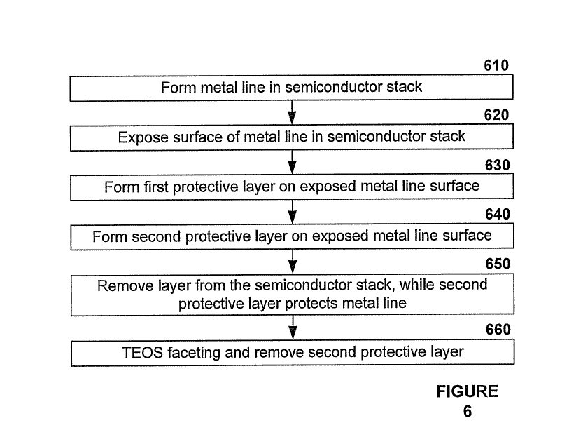

FIG. 5 illustrates faceting of the TEOS layer and removal of the oxide layer. TEOS layer 150 undergoes a faceting operation to facilitate improving the access of openings 195 and 197 to enable improved formation of connector material in openings 195 and 197, where the faceting operation can be utilized to reduce the effective aspect ratio of the openings 195 and 197 and the height of the opening facilitating improved deposition of conductive material subsequently forming an interconnect in opening 195 and 197. Faceting of the TEOS layer 150 can be undertaken with any suitable etch, such as dilute hydrofluoric acid (DHF). During the TEOS faceting, the etch can be utilized to remove SiO₂ layer 124, with silicide layer 122 acting as an etch stop layer to prevent removal of material comprising the metal line 120.

Hence, with the described exemplary, non-limiting embodiment, the potentially challenging trench etch and TEOS faceting operations of the conventional approach, (as described with particular reference to FIGS. 15 and 17) are no longer challenging as the respective oxide layer 124 and silicide layer 122 act as etch stop layers during respective removal of hard mask 160 and faceting of TEOS layer 150. In an exemplary, non-limiting embodiment, the depth of the trench (e.g., trench 197) is in the order of about 150 nm, with a critical dimension of about 30 nm. And, in a further exemplary, non-limiting embodiment, the depth of the via (e.g., via 195) is in the order of about 30-40 nm, with a critical dimension of about 30 nm.

FIG. 6 presents a flow diagram illustrating an exemplary, non-limiting embodiment to facilitate formation of a via (and a subsequently formed interconnect) to connect with a metal line. As previously described, the various exemplary, non-limiting embodiments presented herein, effectively utilize conversion of material comprising a metal line to a silicide and further forming an oxide layer to facilitate prevention of removal of material comprising the metal line and/or the silicide during such processing operations as hard mask removal and TEOS faceting.

At 610, an initial structure is formed as part of formation of a semiconductor component. In an exemplary, non-limiting embodiment, a metal line (e.g., metal line 120) is formed in a substrate (e.g., substrate 110) as part of formation of an electrical circuit in the semiconductor component. As described with reference to FIGS. 1 and 13, the initial structure can be further constructed with other layers being formed over the substrate and metal layer, such as a diffusion barrier layer (e.g., layer 130), a dielectric layer (e.g., layer 140), a TEOS layer (e.g., layer 150), a hard mask layer (e.g., layer 160), a planarization layer (e.g., layer 370), an anti-reflective layer (e.g., layer 380), and a photo-resist layer 390, etc.

At 620, a via (e.g., openings 195 and 197) can be formed in the semiconductor structure. The leading opening of the via (e.g., opening 195) can be controlled (e.g., by resist layer 390 and/or by hard mask layer 160) so that the opening is aligned to expose a surface (e.g., surface 199) of the metal line. The openings comprising the via can be formed by any suitable technique such as anisotropic etch, for example.

At 630, a silicidation operation can be performed during which material at the surface of the metal line (e.g., surface 199) is exposed to an atmosphere comprising silicon. For example, a thermal process can be conducted whereby the surface of metal line is exposed to a soaking atmosphere comprising SiH₄. The silicon-rich atmosphere results in the formation of a silicide layer (e.g., layer 122). In an exemplary, non-limiting embodiment, the metal line can comprise Cu whereby the formed silicide layer comprises copper silicide. The silicide layer can be a result of diffusion of Si into the body of the metal line, thereby forming the region of copper silicide. As previously described, the silicide layer can act as a passivation layer preventing the formation of copper oxide.

At 640, an oxide formation operation can be performed, whereby an oxide layer (e.g., oxide layer 124) forms on top of the silicide layer (e.g., layer 122). In an exemplary, non-limiting embodiment, the oxide layer can be formed as a result of deposition of SiO₂ on the surface of the silicide layer.

At 650, the hard mask layer (e.g., hard mask layer 160) is removed. Any suitable technique can be utilized to remove the hard mask, for example a wet etch. During removal of the hard mask layer the oxide layer has high selectivity to wet etch chemistry and thus acts to isolate the metal line and the silicide layer from the wet etch, thereby preventing unwanted removal of material from the metal line and/or the silicide layer during removal of the hard mask layer.

At 660, to improve the ability to fill the via opening (e.g., openings 195 and 197) the TEOS layer (e.g., layer 150) can be faceted to reduce the effective aspect ratio of the via opening and the height of the opening to facilitate improved deposition of conductive material subsequently forming an interconnect in the via opening. Faceting of the TEOS layer can be undertaken with any suitable etch, such as dilute hydrofluoric acid (DHF), whereby during faceting of the TEOS layer, the etch can be utilized to remove the oxide layer, with the exposed silicide layer acting as an etch stop layer to prevent removal of material comprising the metal line. As previously described, while the metal line has a high conductivity, the conductivity of the silicide layer is of sufficient magnitude to facilitate electrical flow between the via subsequently formed in the final openings (e.g., openings 195 and 197) and the underlying metal line.

### Process for Metal Line Protection by a Reactive Layer

FIGS. 7-11 illustrate a series of exemplary, non-limiting embodiments to facilitate conversion of a capping layer on a metal line to form a metal line protective layer during formation of a via, where the via can be subsequently filled with conductive material to form an interconnect to facilitate electrical coupling with the metal line.

FIG. 7 illustrates an intermediate structure for the formation of a via (and subsequent interconnect) to connect with a metal line. It is to be appreciated that the various layers comprising the exemplary semiconductor stack depicted in FIGS. 7-11 are presented to facilitate understanding of the various concepts presented herein, and the various concepts presented herein can be applied to any suitable semiconductor stack structure. For example, the semiconductor stack illustrated in FIGS. 7-11 can be an intermediate stage in process operations, such that the semiconductor stack is an intermediate stage in a via formation process having a starting structure similar to that illustrated in FIG. 13. The semiconductor stack comprises a substrate layer 210 which has been patterned to facilitate formation of a metal line 220 (and barrier layer 225) therein. A diffusion barrier layer 230 is formed thereover, with the stack being constructed to further comprise a dielectric layer 240, a TEOS layer 250, and a hard mask layer 260 (which has been patterned with an opening as depicted), with openings 295 and 297 partially extending into the semiconductor stack. In comparison with the initial structure presented in FIG. 13, the organic planarization layer (OPL) 370, the Anti-Reflection coating (ARC) layer 380, and resist layer 390, have been removed.

Metal line 220 can be comprised of any suitable conductive material such as aluminum, copper, alloy, etc. In the various embodiments presented herein, metal line 220 is referenced as being comprised of copper, however, it is to be appreciated that the various embodiments can be applied equally to a protective layer being formed on a metal line comprising aluminum, for example. During formation of metal line 220, a capping layer 226 is formed on metal line 220. In an exemplary, non-limiting embodiment, capping layer 226 can comprise of manganese (Mn), whereby Mn layer is segregated from the metal line 220 owing to an oxide layer formed on the surface of the Mn layer during formation of capping layer 226.

As depicted in FIG. 8, a trench etch operation has been performed such that openings 295 and 297 further extend into the semiconductor stack, with further material being removed from TEOS layer 250 and dielectric layer 240, along with material from diffusion barrier layer 230. As shown, in an aspect, the width of combined openings 295 and 297 can be a function of the width of the opening previously formed in the hard mask layer 260. In comparison with the conventional process depicted in FIGS. 13-17, during the trench etch operation the depth of opening 295 is allowed to extend such that the upper surface 227 of the capping layer 226 on metal line 220 is exposed.

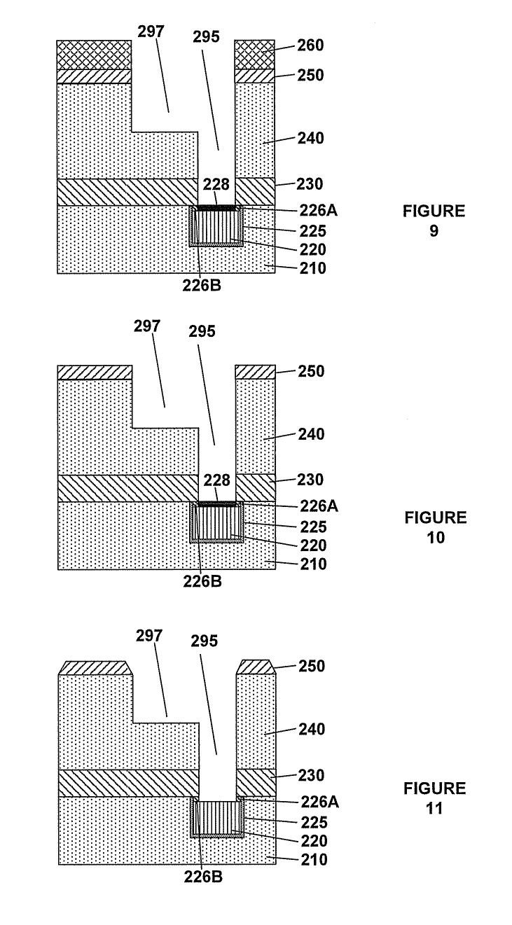

FIG. 9 illustrates an oxidation operation being performed. In an exemplary, non-limiting embodiment, any suitable oxidation operation can be performed, for example a thermal process during which material comprising capping layer 226 is exposed to an oxygen rich atmosphere, such as an annealing process can be conducted whereby material comprising capping layer 226 becomes oxidized. For example, as previously mentioned, capping layer 226 can comprise Mn which can react with the oxygen to form an oxide layer 228 (e.g., comprising manganese oxide). Not all of capping layer 226 may be converted to oxide layer 228 with unreacted portions 226A and 226B of capping layer 226 remaining.

FIG. 10 depicts hard mask layer 260 being removed. Any suitable technique can be utilized to remove the hard mask, for example a wet etch. During removal of the hard mask layer 260, the etch selectivity of the oxide layer 228 acts to isolate metal line 220 from the wet etch, thereby preventing unwanted removal of material from the metal line 220 during removal of the hard mask layer 260.

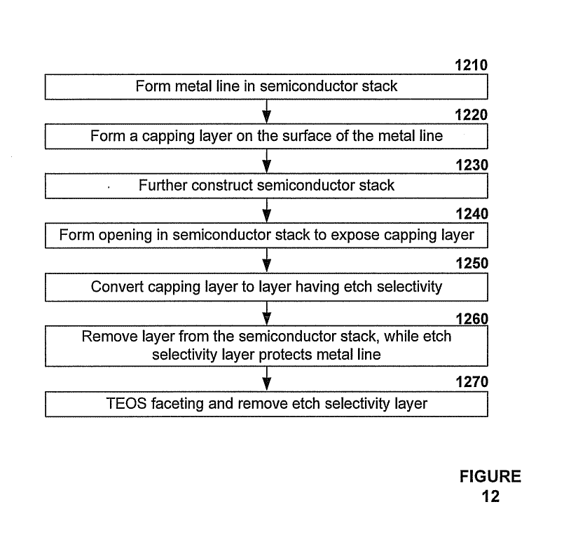

FIG. 11 illustrates faceting of the TEOS layer and removal of the MnOₓ layer. TEOS layer 250 undergoes a faceting operation to facilitate improving the access of openings 295 and 297 to enable improved formation of connector material in openings 295 and 297. Faceting of the TEOS layer 250 can be undertaken with any suitable etch, such as dilute hydrofluoric acid (DHF). During the TEOS faceting, the DHF can be utilized to remove oxide layer 228, thereby exposing metal line 120. Openings 295 and 297 can be subsequently filled with conductive material to facilitate formation of a via connecting to metal line 120.

Hence, with the described exemplary, non-limiting embodiment, the potentially challenging trench etch and TEOS faceting operations of a conventional approach (as described with particular reference to FIGS. 15 and 17) are no longer challenging as the oxide layer 228 acts as an etch stop layer during removal of hard mask 160.

FIG. 12 presents a flow diagram illustrating an exemplary, non-limiting embodiment to facilitate formation of a via (and a subsequently formed interconnect) to connect with a metal line. As previously described, the various exemplary, non-limiting embodiments presented herein, effectively utilize capping a surface of the metal line, and subsequently converting the capping layer to an oxide layer having etch selectivity. The etch selectivity layer facilitates prevention of removal of material comprising the metal line during such processing operations as hard mask removal and TEOS layer faceting.

At 1210, an initial structure is formed as part of formation of a semiconductor component. In an exemplary, non-limiting embodiment, a metal line (e.g., metal line 220) is formed in a substrate (e.g., substrate 210) as part of formation of an electrical circuit in the semiconductor component. In an exemplary, non-limiting embodiment, the metal line can comprise of Cu.

At 1220, a capping layer (e.g., layer 226) is formed on the upper surface of the metal line. In an exemplary, non-limiting embodiment, the capping layer can comprise of manganese (Mn), whereby Mn layer is segregated from the metal line 220 owing to an oxide layer formed on the surface of the Mn layer during formation of capping layer 226.

At 1230, as described with reference to FIGS. 7 and 13, the initial structure can be further constructed with other layers being formed over the substrate and metal layer, such as a diffusion barrier layer (e.g., layer 230), a dielectric layer (e.g., layer 240), a TEOS layer (e.g., layer 250), a hard mask layer (e.g., layer 260), a planarization layer (e.g., layer 370), an anti-reflective layer (e.g., layer 380), and a photo-resist layer (layer 390), etc.

At 1240, a via (e.g., openings 295 and 297) can be formed in the semiconductor structure. The leading opening of the via (e.g., opening 295) can be controlled (e.g., by resist layer 390 and/or by hard mask layer 260) so that the opening is aligned to expose a surface (e.g., surface 227) of the capping layer. The openings comprising the via can be formed by any suitable technique such as anisotropic etch, for example.

At 1250, an oxidation process can be performed whereby material comprising the capping layer is converted to an oxide layer (e.g., Mn is converted to manganese oxide).

At 1260, the hard mask layer (e.g., hard mask layer 260) is removed. Any suitable technique can be utilized to remove the hard mask, for example a wet etch. During removal of the hard mask layer the oxide layer has high selectivity to wet etch chemistry and thus acts to isolate the metal line from the wet etch, thereby preventing unwanted removal of material from the metal line during removal of the hard mask layer.

At 1270, to improve the ability to fill the via opening (e.g., openings 295 and 297) the TEOS layer (e.g., layer 250) can be faceted to reduce the effective aspect ratio of the via opening to the height of the opening facilitating improved deposition of conductive material subsequently forming an interconnect in the via opening. Faceting of the TEOS layer can be undertaken with any suitable etch, such as dilute hydrofluoric acid (DHF), whereby during faceting of the TEOS layer, the etch can be utilized to remove the oxide layer. The opening (e.g., openings 295 and 297) can be subsequently filled with conductive material to facilitate formation of an interconnect connecting to the metal line.

### General Considerations

It is to be appreciated that the various layers, etc., comprising any of the semiconductor stacks presented herein are simply presented to facilitate understanding of the various exemplary, non-limiting embodiments, and application of the exemplary, non-limiting embodiments is not limited to application with semiconductor stacks comprising layers presented herein, but rather can be utilized with any semiconductor stack configuration applicable to the exemplary, non-limiting embodiments.

In brief, the various presented layers comprise of the following. The substrate (e.g., layer 110, 210, 310) can comprise of any suitable material, such as Si, Si-compound, etc. The diffusion barrier layer (e.g., 130, 230, 330) can be present to facilitate prevention of diffusion of atoms comprising the metal line (e.g., 120, 220, 320) into the overlaying dielectric layer (e.g., 140, 240, 340), where the diffusion barrier layer can comprise of any suitable material such as SiN, SiC, SiCN, etc. Dielectric layer (e.g., 140, 240, 340) can comprise a low dielectric layer, an ultra-low dielectric layer (ULK), etc., where a material having a lower k value than SiO₂ can be utilized to prevent intra- and inter-layer capacitance, a suitable material being SiCOH or an organic material, for example.

A tetraethyl orthosilicate (TEOS) layer (e.g., 150, 250, 350) can be utilized to protect the dielectric layer (e.g., 140, 240, 340) from exposure to etching gas chemistry during opening and rework of the hard mask layer (e.g., 160, 260, 360). A hard mask layer (e.g., 160, 260, 360) can be patterned to facilitate control of the shape/extent of the formed trench/via (e.g., 195, 197, 295, 297, 395, 397), the hard mask layer can comprise of titanium nitride (TiN), or any other suitable hard mask material such as TaN, silicon dioxide, silicon nitride, silicon oxynitride, boronitride, silicon boronitride, silicon carbide, and the like, and formed by any suitable technique such as chemical vapor deposition (CVD) or advanced spin-on methods.

A planarization layer 370 can be utilized to facilitate formation of a smooth surface to enable improved lithography, where planarization layer 370 can comprise of any suitable material such as an organic planarization layer (OPL). Further, an anti-reflective layer 380 can be utilized to prevent light interference during lithography of the resist layer (e.g., 390), where the anti-reflective layer 380 can comprise of an Anti-Reflection coating (ARC, e.g., SiARC) layer, or other suitable material. A photo-resist layer 390 can be utilized to facilitate patterning for construction of the via (e.g., to form openings 195, 295, 395, etc.), as part of a via lithography operation. Stripping of a resist layer (e.g., photo-resist layer 390, etc.) comprises removal of unwanted resist from the semiconductor stack, while preventing removal of underlying layers and materials. Any suitable stripper can be utilized as required, such as organic stripper, inorganic stripper, dry stripping, etc.

The various layers presented above can be formed/deposited by any suitable process such as a spin coating, deposition, CVD process, for example, low pressure chemical vapor deposition (LPCVD), plasma enhanced chemical vapor deposition (PECVD), etc.

Any suitable technique can be used to pattern any of the material layers presented herein. For example, patterning can be created by employing a photoresist (e.g., photo-resist layer 390) which is patterned using standard photolithographic techniques to form the required pattern to create the pattern, trenches, openings, etc., wherein the photoresist is exposed to electromagnetic radiation through a mask having an image pattern of a desired layout (e.g., desired trenches, openings, line patterning, etc.). Openings are then formed in the photoresist in order to form the desired layout, e.g., by etching away the exposed material (in the case of a positive photoresist) or etching away the unexposed material (in the case of a negative photoresist). Depending on the material of the photoresist, exposure can create a positive or a negative. With a positive photoresist, exposure causes a chemical change in the photoresist such that the portions of the photoresist layer exposed to light become soluble in a developer. With a negative photoresist, the chemical change induced by exposure renders the exposed portions of the photoresist layer insoluble to the developer. After exposure and develop, a layout according to the desired pattern is laid out on the first layer. A subsequent processing step, such as an etching step or an ion implantation step, can be performed and controlled according to the layout. For instance, after exposure and develop, material in the first layer not covered by the photoresist layer can be etched, thus transferring the pattern to the first layer. The photoresist can be subsequently removed. Etching can be by any viable dry or wet etching technique. For example, a wet or dry etching technique can be employed for patterning, while in another aspect, etching can be by a specific anisotropically etch.

Any etching/material removal technique is applicable to the various embodiments, as described herein. Wet etching can be utilized to remove a particular layer where a given layer may be susceptible to etch by a particular etchant while a neighboring layer is not (e.g., selective etching utilized to remove hard mask layer 360). In another example, anisotropic etching techniques can be utilized to control material removal in a specific direction (unlike standard wet etching) such as vertically down into a stack to form an opening, etc.

Levelling of layers after formation can be by any suitable technique, e.g., by chemical mechanical polish/planarization (CMP) or other suitable process, to achieve a given dimension, in preparation for the next stage in creation of the replacement gate/contact structure, etc.

It is to be appreciated that while the formation of a via connecting to a metal line is described, there may be certain procedures that are not fully disclosed during description of the various embodiments as presented herein. However, rather than provide description of each and every operation involved in the various operations facilitating formation, patterning, removal, etc., of each structure presented herein, for the sake of description only the general operations are described. Hence, while no mention may be presented regarding a particular operation pertaining to aspects of a particular figure, it is to be appreciated that any necessary operation, while either not fully disclosed, or not mentioned, to facilitate formation/deconstruction of a particular layer/element/aspect presented in a particular figure is considered to have been conducted. For example, while no mention may be made regarding a layer described in a preceding figure being leveled (e.g., by chemical mechanical polish, or other suitable operation) it is considered, for the sake of readability of the various exemplary embodiments presented herein, that the leveling process occurred, as have any other necessary operations. It is appreciated that the various operations, e.g., leveling, chemical mechanical polish, patterning, photolithography, deposition, layer formation, etching, etc., are well known procedures and are not necessarily expanded upon throughout this description.

The claimed subject matter has been described with reference to the drawings, wherein like reference numerals are used to refer to like elements throughout. In the description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

It is to be appreciated that the various Figures illustrating the various embodiments presented herein are simply rendered to facilitate understanding of the various embodiments. Accordingly, the various embodiments can be applicable to respective elements of any dimension, scaling, area, volume, distance, etc., and while a Figure may illustrate a dimension of one element rendered in association with another element, the respective dimensions, scaling, ratios, etc., are not limited to those as rendered but can be of any applicable magnitude.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim. The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A semiconductor structure, comprising:
a plurality of layers including a mask layer;
a via opening through the plurality of layers including the mask layer;
a metal line, wherein a surface of the metal line is exposed by the via opening;
a passivation layer, wherein the passivation layer is formed from a portion of the metal line exposed by the via opening; and
an etch selectivity layer, wherein the etch selectivity layer is formed on the passivation layer.

2. The semiconductor of claim 1, wherein the passivation layer comprises a silicide formed by chemical modification of a portion of the metal line exposed by the via opening.

3. The semiconductor of claim 1, wherein the metal line comprises copper.

4. The semiconductor of claim 1, wherein the passivation layer comprises copper silicide formed by chemical modification of a portion of the metal line.

5. The semiconductor of claim 1, wherein the etch selectivity layer comprises an oxide.

6. The semiconductor of claim 1, wherein the etch selectivity layer comprises silicon oxide.

7. The semiconductor of claim 1, wherein the etch selectivity layer protects at least one of a portion of the passivation layer or a portion of the metal line during removal of the mask layer.

8. The semiconductor of claim 1, wherein in the event of removal of at least the mask layer the via opening is filled with conductive material to form an interconnect.

9. The semiconductor of claim 8, wherein the interconnect connects with the passivation layer exposed by removal of the etch selectivity layer.

10. A method for forming a semiconductor device, comprising:
forming a semiconductor stack comprising a metal line and a plurality of layers including a mask layer;
forming a via in the semiconductor stack exposing a surface of the metal line;
converting a portion of the exposed surface of the metal line to form a passivation layer; and
forming a protective layer on the passivation layer.

11. The method of claim 10, wherein the metal line comprises copper.

12. The method of claim 10, wherein the passivation layer comprises a silicide.

13. The method of claim 10, wherein the passivation layer comprises copper silicide.

14. The method of claim 10, wherein the protective layer comprises an oxide.

15. The method of claim 10, further comprising removing the mask layer, whereby the protective layer preventing removal of at least one of a portion of the passivation layer or a portion of the metal line.

16. The method of claim 15, further comprising, in the event of removal of at least the mask layer the via opening is filled with conductive material to form an interconnect.

17. The method of claim 16, wherein the interconnect connecting with the passivation layer exposed by removing the etch selectivity layer.

18. A semiconductor structure, comprising:
a plurality of layers including a mask layer;
a via opening formed through the plurality of layers including the mask layer;
a metal line located in a layer comprising the plurality of layers, wherein the metal line further comprising a capping layer, the capping layer is exposed by the via opening.

19. The semiconductor structure of claim 18, wherein the capping layer is chemically modified to comprise material having etch selectivity to an etch utilized to subsequently remove the mask layer.

20. The semiconductor structure of claim 18, wherein the metal layer comprises copper, and the capping layer comprises manganese.
